(19) United States
(12) Patent Application Publication
(10) Pub. No.: US 2025/0259954 A1
(43) Pub. Date: Aug. 14, 2025

(54) SOLDER BALL, SEMICONDUCTOR PACKAGE INCLUDING THE SAME, AND METHOD OF MANUFACTURING THE SAME

(71) Applicant: Samsung Electronics Co., Ltd., Suwon-si (KR)

(72) Inventors: Seungjin OH, Suwon-si (KR); Myoungchul EUM, Suwon-si (KR); Taehyung KIM, Suwon-si (KR)

(73) Assignee: Samsung Electronics Co., Ltd., Suwon-si (KR)

(21) Appl. No.: 18/979,833

(22) Filed: Dec. 13, 2024

(30) Foreign Application Priority Data
Feb. 13, 2024 (KR) 10-2024-0020661

(51) Int. Cl. H01L 23/00; H01L 23/498; H01L 25/065; H10B 80/00

(52) U.S. Cl. CPC H01L 24/13; H01L 23/49838; H01L 24/11; H01L 24/14; H01L 24/16; H01L 23/49833; H01L 24/32; H01L 24/73; H01L 25/0652; H01L 2224/11312; H01L 2224/1183; H01L 2224/13005; H01L 2224/13111; H01L 2224/13324; H01L 2224/13339; H01L 2224/13344; H01L 2224/13347; H01L 2224/1336; H01L 2224/13366; H01L 2224/13487; H01L 2224/1403; H01L 2224/16145; H01L 2224/16227; H01L 2224/32145; H01L 2224/32225; H01L 2224/73204; H01L 2924/3512; H10B 80/00

(57) ABSTRACT

A solder ball includes a solder member having a spherical shape and crack prevention members including a plurality of conductive wires irregularly distributed in the solder member and ceramic coating layers covering surfaces of the plurality of conductive wires.

### CROSS-REFERENCE TO RELATED APPLICATION

This application is based on and claims priority under 35 U.S.C. § 119 to Korean Patent Application No. 10-2024-0020661, filed on Feb. 13, 2024, in the Korean Intellectual Property Office, the disclosure of which is incorporated by reference herein in its entirety.

### BACKGROUND

The inventive concepts relate to solder balls, semiconductor packages including the solder balls, and methods of manufacturing the solder balls and the semiconductor packages.

Electronic apparatuses are becoming more compact and lightweight according to the rapid development of the electronics industry and users' demand. As the electronic apparatuses become smaller and lighter, semiconductor packages used therein are also becoming smaller and lighter. In addition, semiconductor packages with high reliability along with high performance and large capacity are required. The temperature of the semiconductor packages increases significantly when operating due to high integration thereof, and excessive loads are applied to solder balls due to harsh use environments, such as repeated thermal cycles between high and low temperatures. Recently, research has been conducted to prevent cracks caused by the loads applied to the solder balls.

### SUMMARY

The inventive concepts provide solder balls with improved reliability, semiconductor packages including the solder balls, and methods of manufacturing the solder balls and the semiconductor packages.

Example embodiments of the inventive concepts are not limited to the example embodiments described in the present disclosure, but some other example embodiments not described herein will be clearly understood by those skilled in the art from the following description.

According to an example embodiment of the inventive concepts, a solder ball may include a solder member having a spherical shape and crack prevention members including a plurality of conductive wires irregularly distributed in the solder member and ceramic coating layers covering surfaces of the plurality of conductive wires.

According to an example embodiment of the inventive concepts, a semiconductor package may include a first package substrate, at least one semiconductor chip mounted on the first package substrate using a flip chip method, and a first solder ball attached to an active surface of the at least one semiconductor chip, wherein the first solder ball includes a first solder member having a spherical shape and first crack prevention members including a plurality of first conductive wires irregularly distributed in the first solder member and first ceramic coating layers covering surfaces of the plurality of first conductive wires.

According to an example embodiment of the inventive concepts, a method of manufacturing a solder ball may include filling a chamber with molten metal, injecting crack prevention members into the molten metal, stirring the molten metal so that the crack prevention members are uniformly distributed in the molten metal, and forming the solder ball by dropping the molten metal using vibration of a generator provided in the chamber.

According to an example embodiment of the inventive concepts, a method of manufacturing a semiconductor package may include preparing a package substrate, filling a chamber with molten metal, injecting crack prevention members into the molten metal, stirring the molten metal so that the crack prevention members are uniformly distributed in the molten metal, forming a solder ball by dropping the molten metal using vibration of a generator provided in the chamber, and attaching the solder ball to a lower pad of a package substrate.

### BRIEF DESCRIPTION OF THE DRAWINGS

Some example embodiments will be more clearly understood from the following detailed description taken in conjunction with the accompanying drawings in which:

FIG. 1 is a cross-sectional view showing a portion of a semiconductor package including a solder ball according to an example embodiment;

FIG. 2 is a cross-sectional view showing a case in which a crack occurs in the solder ball shown in FIG. 1;

FIG. 3 is an enlarged view of region CX1 of FIG. 1;

FIG. 4 is a cross-sectional view of a semiconductor package including solder balls according to an example embodiment;

FIG. 5 is a cross-sectional view of a semiconductor package including solder balls according to an example embodiment;

FIG. 6 is a cross-sectional view of a semiconductor package including solder balls according to an example embodiment;

FIG. 7 is a flowchart of a method of manufacturing a solder ball, according to an example embodiment;

FIGS. 8 to 11 are diagrams sequentially showing a process of manufacturing a solder ball, according to an example embodiment;

FIGS. 12 and 13 are diagrams sequentially showing a process of manufacturing a solder ball, according to an example embodiment;

FIGS. 14 and 15 are flowcharts of a method of manufacturing a semiconductor package, according to an example embodiment; and

FIGS. 16 to 23 are diagrams sequentially showing a process of manufacturing a semiconductor package including solder balls, according to an example embodiment.

### DETAILED DESCRIPTION

Hereinafter, some example embodiments are described in detail with reference to the accompanying drawings. The inventive concepts may, however, be embodied in different forms and should not be construed as limited to the example embodiments set forth herein. The following example embodiments are provided to sufficiently convey the scope of the inventive concepts to those skilled in the art and to make the inventive concept thorough and complete.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

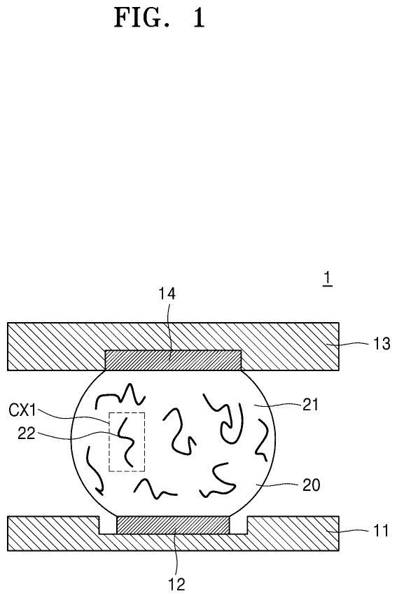

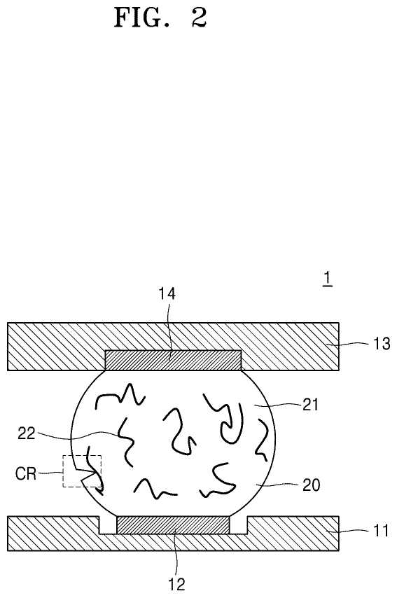

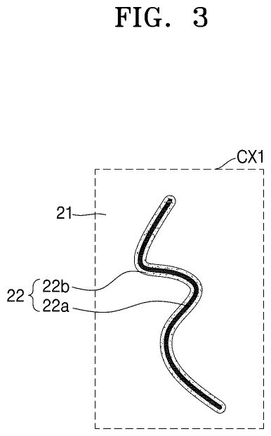

FIG. 1 is a cross-sectional view showing a portion of a semiconductor package 1 including a solder ball 20 according to an example embodiment. FIG. 2 is a cross-sectional view showing a case in which a crack occurs in the solder ball 20 shown in FIG. 1, and FIG. 3 is an enlarged view of region CX1 of FIG. 1. A description is given below with reference to FIGS. 1 to 3.

For example, the semiconductor package 1 may include a wiring substrate 11, a solder ball land 12, a board substrate 13, a conductive pad 14, and the solder ball 20.

The wiring substrate 11 may include a printed circuit board (PCB). The solder ball land 12 may be disposed on the upper surface of the wiring substrate 11, and the solder ball land 12 shown in FIG. 1 may include a non-solder mask defined (NSMD) ball land. However, the ball land to which the solder ball 20 according to an example embodiment is attached is not limited to the NSMD-type ball land and may include a solder mask defined (SMD) ball land. The outer circumferential portion of the solder ball land 12 according to an example embodiment may be exposed via an open region. The solder ball land 12 may include a metal layer. The solder ball land 12 may include a single layer or a composite layer, which includes metal, such as tin, silver, or copper.

The board substrate 13 may be spaced apart from the upper surface of the wiring substrate 11 in a vertical direction. The board substrate 13 may include a conductive pad 14 disposed on the upper surface thereof. The conductive pad 14 of the board substrate 13 may be fused with the solder ball 20. The conductive pad 14 may include a metal layer like the solder ball land 12, and the conductive pad 14 may include a single layer or a composite layer, which includes metal, such as tin, silver, or copper.

The solder ball 20 may be located between the solder ball land 12 and the conductive pad 14 and serve as an electrical path between the wiring substrate 11 and the board substrate 13.

The solder ball 20 according to an example embodiment may include a solder member 21 having a spherical shape and a crack prevention member 22 located in the solder member 21. According to an example embodiment, the solder member 21 may include tin (Sn), indium (In), bismuth (Bi), antimony (Sb), copper (Cu), silver (Ag), zinc (Zn), lead (Pb), and/or an alloy thereof. For example, the solder member 21 may have a spherical or ball shape and include a tin-containing alloy (e.g., Sn—Ag—Cu). According to an example embodiment, the diameter of the solder member 21 may be in a range from about 20 micrometers to about 800 micrometers.

According to an example embodiment, crack prevention members 22 may include a plurality of conductive wires 22a irregularly distributed in the solder member 21 and ceramic coating layers 22b covering the surfaces of the plurality of conductive wires 22a. The crack prevention members 22 may be irregularly distributed in the solder member 21.

According to some example embodiments, some of the crack prevention members 22 may be in contact with the solder ball land 12 or the conductive pad 14. However, ideally, it is desirable that the crack prevention members 22 are not in contact with the solder ball land 12 or the conductive pad 14. The surfaces of the crack prevention members 22 have been coated with the ceramic coating layers 22b. Therefore, when a large amount of the crack prevention members 22 comes into contact with the solder ball land 12 or the conductive pad 14, the conductivity of the solder ball land 12 or the conductive pad 14 may deteriorate.

In addition, it is desirable that the plurality of crack prevention members 22, which are irregularly distributed in the solder member 21, are evenly arranged in the outer circumferential region and central region in the solder member 21. As shown in FIG. 2, when a crack occurs in the solder member 21, the crack prevention member 22 may mitigate or prevent the crack from spreading. In other words, when the crack prevention member 22 is located at an angle to a cross-section of the solder member 21 that is split due to the occurrence of crack (e.g., when the crack prevention member 22 is placed perpendicular to the cross-section), the spread of the crack is stopped at the crack prevention member 22.

The crack in the solder ball 20 may occur due to thermal stress or mechanical stress, such as shock and/or vibration. The crack may occur from the surface of the solder member 21 due to external shock or vibration, and the crack due to thermal stress may occur from the inside of the solder member 21. Therefore, in order to effectively reduce or prevent both cracks due to mechanical stress and cracks due to thermal stress, it is desirable that the plurality of crack prevention members 22 are evenly arranged in the outer circumferential region and central region in the solder member 21.

According to an example embodiment, the melting point of the crack prevention member 22 is higher than the melting point of the solder member 21. During a process of manufacturing the solder ball 20, the crack prevention members 22 may be put into a melted solder member 21, which is described below in detail. The solder member 21 is in a liquid state, but the crack prevention member 22 put into the solder member 21, which is in the liquid state, is desirable to be in a solid state and maintains the shape thereof.

Each of the conductive wires 22a may include a conductive material, and the conductive material may include iron (Fe), titanium (Ti), gold (Au), silver (Ag), copper (Cu), aluminum (Al), or a combination thereof. The surfaces of the conductive wires 22a may be coated with the ceramic coating layers 22b, respectively. The ceramic coating layer 22b may include a silica compound or an alumina compound, but example embodiment are not necessarily limited thereto.

The ceramic coating layer 22b may serve as a barrier to reduce or prevent metal materials constituting the conductive wire 22a from diffusing into the solder member 21 or from causing a chemical reaction with the solder member 21. According to an example embodiment, the ceramic coating layer 22b may be replaced with an insulating barrier film and/or a conductive barrier film. The insulating barrier film may include an oxide film, a nitride film, a carbide film, polymer, or a combination thereof. The conductive barrier film may include, for example, a metal compound, such as tungsten nitride (WN), titanium nitride (TiN), or tantalum nitride (TaN).

According to an example embodiment, the diameter of the conductive wire 22a may be in a range from about 1 micrometer to 50 micrometers. When the diameter of the conductive wire 22a is less than 1 micrometer and a crack occurs in the solder member 21, the crack prevention member 22 may not function properly as a barrier to the crack and may be damaged along with the solder member 21. When the diameter of the conductive wire 22a is greater than 50 micrometers, the conductive wire 22a may become too thick and a sufficient number of crack prevention members 22 may not be properly distributed in the solder member 21.

The length of the conductive wire 22a may be in a range from about 1 micrometer to about 100 micrometers. When the length of the conductive wire 22a is less than 1 micrometer and a crack occurs in the solder member 21, the crack prevention member 22 may not have a sufficient area to serve as a barrier to the crack. Also, when the length of the conductive wire 22a is greater than 100 micrometers, the probability that the crack prevention members 22 come into contact with the solder ball land 12 or the conductive pad 14 increases, which may deteriorate the conductivity of the solder ball land 12 or the conductive pad 14. In addition, assuming that the solder member 21 provides an electrical connection path between the solder ball land 12 and the conductive pad 14, the deterioration of conductivity indicates that the crack prevention member 22 blocks the electrical connection path.

According to an example embodiment, an amount of the solder member 21 in the solder ball 20 may be in a range from about 40 wt % to about 98 wt %, and an amount of the crack prevention member 22 in the solder ball 20 may be in a range from about 2 wt % to about 60 wt %. When the amount of the solder member 21 is less than 40 wt %, the solder ball 20 may not properly serve as an electrical path between the solder ball land 12 and the conductive pad 14. When the amount of the solder member 21 is greater than 98 wt %, the amount of the crack prevention member 22 becomes too small. Therefore, if a crack occurs in the solder member 21, the crack may not be properly blocked or prevented.

In another example embodiment, the solder ball 20 may further include a dopant. The dopant may include indium (In), bismuth (Bi), antimony (Sb), copper (Cu), silver (Ag), zinc (Zn), or lead (Pb). However, the materials of the dopant are not limited to the listed materials. When the amount of the dopant in the solder ball 20 increases, the material strength of the solder member 21 may be increased.

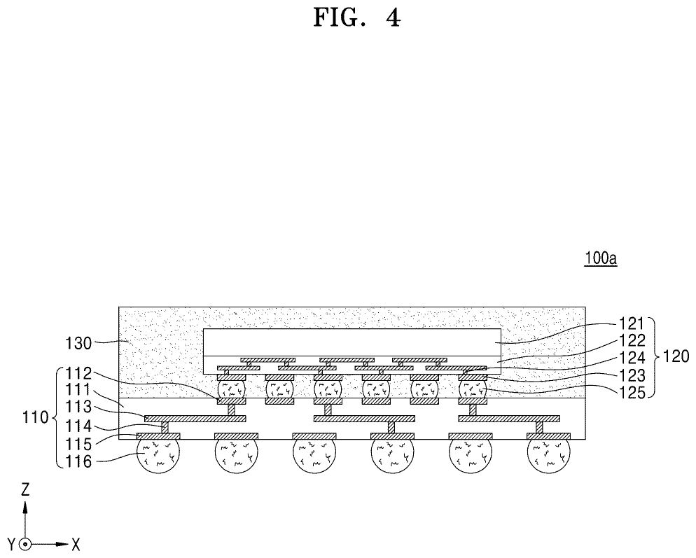

FIG. 4 is a cross-sectional view of a semiconductor package 100a including solder balls 116 according to an example embodiment. A description is given below with reference to FIG. 4.

The semiconductor package 100a according to an example embodiment may include a package substrate 110, a semiconductor chip 120, and a molding layer 130.

The package substrate 110 may include an insulating layer 111, an upper pad 112, a conductive pattern 113, a conductive via 114, a lower pad 115, and a solder ball 116. The package substrate 110 may be formed based on a PCB, a wafer substrate, a ceramic substrate, or a glass substrate. In an example embodiment, the package substrate 110 may include a PCB. However, the package substrate 110 is not limited to the PCB.

The insulating layer 111 may constitute a body portion of the package substrate 110. The insulating layer 111 may include, for example, an inorganic insulating material, an organic insulating material, or a combination thereof. The inorganic insulating material may include, for example, silicon oxide, silicon nitride, or a combination thereof. The organic insulating material may include, for example, polyimide, epoxy resin, or a combination thereof.

The upper pad 112 may be located at the upper end of the insulating layer 111. The upper pad 112 may include an input terminal and/or an output terminal that electrically connects the package substrate 110 to the semiconductor chip 120. A chip connection terminal 125 of the semiconductor chip 120 may be attached to the upper pad 112, which is described below.

As used herein, a direction parallel to the upper surface of the package substrate 110 may be defined as a first horizontal direction (an X direction), and a direction parallel to the upper surface of the package substrate 110 and perpendicular to the first horizontal direction (the X direction) may be defined as a second horizontal direction (a Y direction). A direction perpendicular to the upper surface of the package substrate 110 and orthogonal to both the first horizontal direction (the X direction) and the second horizontal direction (the Y direction) may be defined as a vertical direction (a Z direction).

The conductive pattern 113 may be provided in plurality, and the plurality of conductive patterns 113 may be buried in the insulating layer 111 and extend in lateral directions (the X direction and/or the Y direction). The plurality of conductive patterns 113 may have different vertical levels. The conductive via 114 may be located between the plurality of conductive patterns 113 at different vertical levels and extend in the vertical direction (the Z direction). The conductive via 114 may be in contact with the plurality of conductive patterns 113 at different vertical levels. The conductive via 114 may be in contact with the lower surface of the conductive pattern 113 at a relatively high vertical level and the upper surface of the conductive pattern 113 at a relatively low vertical level.

The lower pad 115 may be located at the lower end of the insulating layer 111. The lower pad 115 may include an input terminal and/or an output terminal that electrically connects the semiconductor package 100a to an external electronic device. The solder ball 116 may be attached to the lower pad 115, which is described below.

The upper pad 112, the conductive pattern 113, the conductive via 114, and the lower pad 115 may include conductive materials. The conductive materials may include copper (Cu), gold (Au), silver (Ag), nickel (Ni), tungsten (W), aluminum (Al), or a combination thereof. In addition, in some example embodiments, the upper pad 112, the conductive pattern 113, the conductive via 114, and the lower pad 115 may further include barrier materials for blocking or preventing the conductive materials from diffusing out of the upper pad 112, the conductive pattern 113, the conductive via 114, and the lower pad 115, respectively. The barrier materials may include, for example, titanium (Ti), tantalum (Ta), titanium nitride (TiN), tantalum nitride (TaN), or a combination thereof.

At least one of a control signal, a power signal, or a ground signal for operation of the semiconductor package 100a may be provided from the outside via the solder ball 116. A data signal to be stored in the semiconductor package 100a may be provided from the outside via the solder ball 116, or data stored in the semiconductor package 100a may be provided to the outside via the solder ball 116.

According to an example embodiment, the semiconductor chip 120 may be mounted on the package substrate 110. Although the diagram shows a case in which there is only one semiconductor chip 120, a plurality of semiconductor chips 120 may be mounted on the package substrate 110 according to some example embodiments.

The semiconductor chip 120 may include a memory chip or a logic chip.

The memory chip may include a volatile memory chip or a non-volatile memory chip. The volatile memory chips may include, for example, existing volatile memory chips, such as dynamic random access memory (DRAM), static RAM (SRAM), thyristor RAM (TRAM), zero capacitor RAM (ZRAM), or twin transistor RAM (TTRAM), and volatile memory chips currently under development. In addition, the non-volatile memory chips may include, for example, existing non-volatile memory chips, such as flash memory, magnetic RAM (MRAM), spin-transfer torque MRAM (STT-MRAM), ferroelectric RAM (FRAM), phase change RAM (PRAM), resistive RAM (RRAM), nanotube RRAM, polymer RAM, nano floating gate memory, holographic memory, molecular electronics memory, or insulator resistance change memory, and non-volatile memory chips currently under development.

The logic chip may be provided as, for example, a microprocessor, a graphics processor, a signal processor, a network processor, a chipset, an audio coder-decoder (codec), a video codec, an application processor, or a system on chip, but example embodiment are not limited thereto. The microprocessor may include, for example, a single core or multiple cores.

The semiconductor chip 120 may include a semiconductor substrate 121, a semiconductor device layer 122, a chip connection pad 123, a semiconductor wiring layer 124, and a chip connection terminal 125.

The semiconductor substrate 121 of the semiconductor chip 120 may have an active surface and an inactive surface opposite to the active surface. The active surface of the semiconductor substrate 121 may face the upper surface of the package substrate 110. A plurality of active/passive devices may be formed on the active surface of the semiconductor substrate 121, and the chip connection pad 123 may also be formed thereon.

The chip connection terminal 125 may be formed between the package substrate 110 and the active surface of the semiconductor chip 120. The chip connection terminal 125 may be in contact with the chip connection pad 123. The semiconductor chip 120 may be electrically connected to the package substrate 110 via the chip connection terminal 125.

The semiconductor substrate 121 may include a semiconductor device layer 122 that is formed on the active surface of the semiconductor substrate 121. The semiconductor wiring layer 124 may be formed in the semiconductor device layer 122 and electrically connected to the chip connection terminal 125 via the chip connection pad 123.

The semiconductor substrate 121 may include, for example, silicon. The semiconductor substrate 121 may include semiconductor elements, such as germanium, or compound semiconductors, such as silicon carbide (SiC), gallium arsenide (GaAs), indium arsenide (InAs), and indium phosphide (InP). The semiconductor substrate 121 may have a silicon on insulator (SOI) structure. For example, the semiconductor substrate 121 may include a buried oxide (BOX) layer. The semiconductor substrate 121 may include a conductive region, for example, a well doped with impurities or a structure doped with impurities. Further, the semiconductor substrate 121 may have various device isolation structures, such as a shallow trench isolation (STI) structure.

The semiconductor device layer 122 may include the semiconductor wiring layer 124 for connecting a plurality of individual devices to other wires formed on the semiconductor substrate 121. The semiconductor wiring layer 124 may include at least one metal wiring layer and a via plug. For example, the semiconductor wiring layer 124 may have a multi-layer structure in which two or more metal wiring layers or two or more via plugs are alternately stacked on each other.

The chip connection pad 123 may be disposed on the semiconductor device layer 122 and electrically connected to the semiconductor wiring layer 124 inside the semiconductor device layer 122. The semiconductor wiring layer 124 may be electrically connected to the chip connection terminal 125 via the chip connection pad 123. For example, the chip connection pad 123 may include at least one of aluminum (Al), copper (Cu), nickel (Ni), tungsten (W), platinum (Pt), or gold (Au).

A passivation layer (not shown) may be formed on the semiconductor device layer 122 so as to protect the semiconductor wiring layer 124 in the semiconductor device layer 122 and other structures below the semiconductor wiring layer 124 from external impact or moisture. The passivation layer may expose at least a portion of the upper surface of the chip connection pad 123.

The chip connection terminal 125 may be disposed on the chip connection pad 123. The chip connection terminal 125 may be used to electrically connect the semiconductor chip 120 to the package substrate 110. At least one of a control signal, a power signal, or a ground signal for operation of the semiconductor chip 120 may be provided from the outside via the chip connection terminal 125. A data signal to be stored in the semiconductor chip 120 may be provided from the outside via the chip connection terminal 125, or data stored in the semiconductor chip 120 may be provided to the outside via the chip connection terminal 125.

The solder ball 116 and the chip connection terminal 125 shown in FIG. 4 are examples of the solder ball 20 described with reference to FIGS. 1 to 3.

The semiconductor package 100a may further include the molding layer 130 configured to seal the semiconductor chip 120. The molding layer 130 may surround the side surface, lower surface, and upper surface of the semiconductor chip 120. However, unlike the configuration shown in the diagram, the upper surface of the semiconductor chip 120 may be exposed via the upper surface of the molding layer 130.

The molding layer 130 may be provided as, for example, an epoxy molding compound (EMC). However, the molding layer 130 is not limited to the EMC and may include various materials, such as epoxy-based materials, thermosetting materials, thermoplastic materials, and ultraviolet (UV)-treated materials. The thermosetting materials may include phenol-based, acid anhydride-based, or amine-based curing agents and acrylic polymer additives.

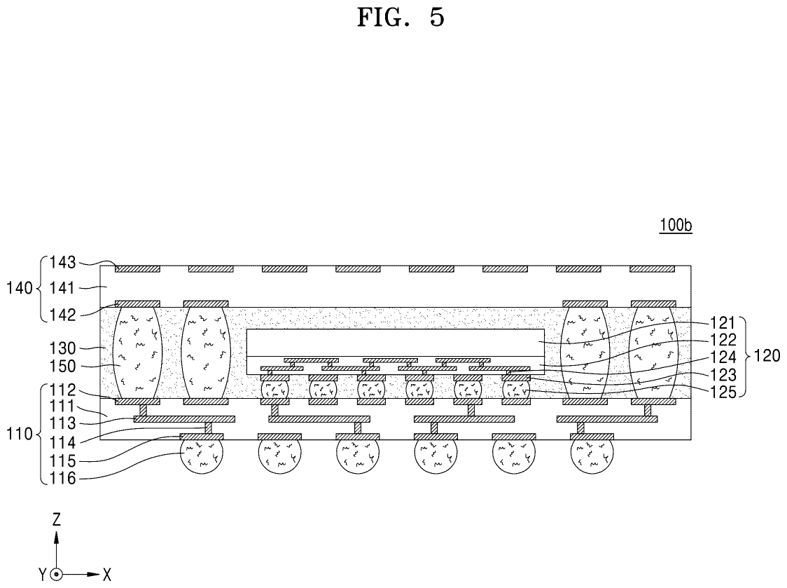

FIG. 5 is a cross-sectional view of a semiconductor package 100b including solder balls 116 according to an example embodiment. The semiconductor package 100b illustrated in FIG. 5 is the same as or substantially similar to the semiconductor package 100a illustrated in FIG. 4, except that the semiconductor package 100b further includes an upper package substrate 140 and a connector 150. Therefore, descriptions of the components already given above with reference to FIG. 4 are omitted.

Referring to FIG. 5, the semiconductor package 100b may further include the upper package substrate 140 disposed on the semiconductor chip 120 and the connector 150 located between the package substrate 110 and the upper package substrate 140.

The upper package substrate 140 may be the same as or substantially similar to the package substrate 110 disposed on the active surface of the semiconductor chip 120, except that the upper package substrate 140 is disposed on the inactive surface of the semiconductor chip 120. The upper package substrate 140 may include an upper insulating layer 141, a first upper package substrate pad 142, and a second upper package substrate pad 143.

Because the upper insulating layer 141 may have the same or substantially similar configuration as the insulating layer 111 (see FIG. 4) described with reference to FIG. 4, detailed descriptions thereof are omitted. A conductive pattern (not shown) extending in the lateral directions (the X direction and/or the Y direction) and a conductive via (not shown) extending in the vertical direction (the Z direction) may be arranged in the upper insulating layer 141 like the insulating layer 111 (see FIG. 4).

The first upper package substrate pad 142 may be located at the lower end of the upper insulating layer 141. Also, the first upper package substrate pad 142 may be electrically and physically connected to the upper end of the connector 150. The second upper package substrate pad 143 may be located at the upper end of the upper insulating layer 141 and may be electrically connected to other semiconductor devices (e.g., semiconductor packages) arranged on the upper package substrate 140.

The connector 150 may electrically connect the package substrate 110 to the upper package substrate 140. The connector 150 may include a solder ball that is formed by bonding a solder ball attached to an upper pad 112 of the package substrate 110 to a solder ball (not shown) attached to the first upper package substrate pad 142. Accordingly, the connector 150 is an example of the solder ball 20 (see FIG. 1) described with reference to FIGS. 1 to 3. The crack prevention members 22 (see FIG. 1) shown in FIGS. 1 to 3 may be irregularly distributed in the connector 150.

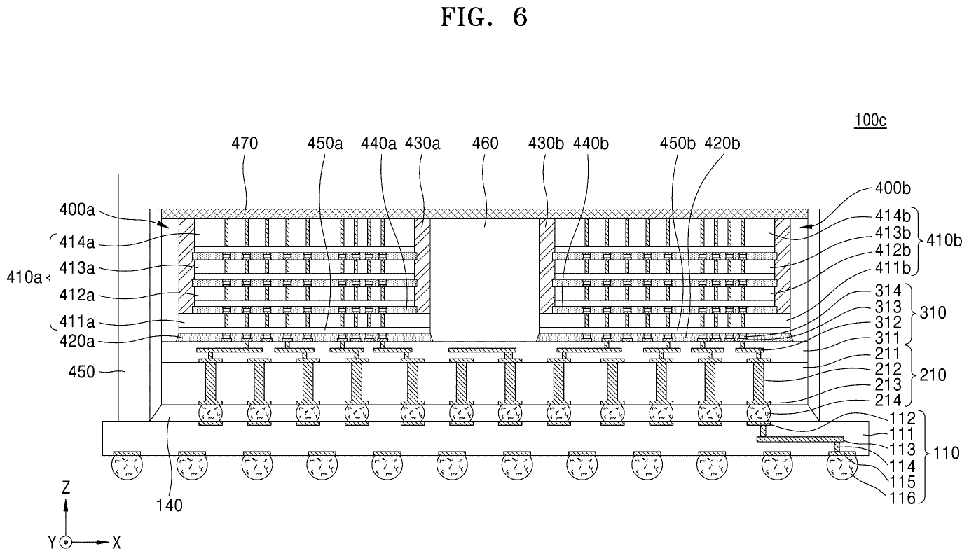

FIG. 6 is a cross-sectional view of a semiconductor package 100c including solder balls 116 according to another embodiment. The semiconductor package 100c shown in FIG. 6 includes an interposer 210. A description is given below with reference to FIG. 6.

Referring to FIG. 6, the semiconductor package 100c may include a package substrate 110, a first underfill 140, the interposer 210, an interposer redistribution structure 310, a first memory device 400a, and a second memory device 400b. The first and second memory devices 400a and 400b may include a plurality of memory chips 410a and 410b, respectively.

Because a package substrate 110 shown in FIG. 6 is the same as or substantially similar to the package substrate 110 shown in FIG. 4, detailed descriptions thereof are omitted below. For example, a solder ball 116 shown in FIG. 6 is an example of the solder ball 20 (see FIG. 1) described with reference to FIGS. 1 to 3.

The interposer 210 may include an interposer substrate 211, a through-electrode 212, an interposer pad 213, and an interposer connection terminal 214.

The first memory device 400a and the second memory device 400b may be mounted on the interposer 210. The interposer 210 is shown as a silicon interposer substrate including a through silicon via (TSV), but interposers applicable to example embodiments are not limited thereto. For example, the interposer 210 may include a redistribution substrate.

The interposer substrate 211 may have a first surface facing the package substrate 110 and a second surface facing the first and second memory devices 400a and 400b and opposite to the first surface of the interposer substrate 211. The interposer substrate 211 may include semiconductor elements, such as silicon and germanium, or compound semiconductors, such as silicon carbide (SiC), gallium arsenide (GaAs), indium arsenide (InAs), and indium phosphide (InP).

The through-electrode 212 may include a TSV that passes through the interposer substrate 211 in a vertical direction (e.g., in the Z direction). The through-electrode 212 may provide an electrical path that connects the interposer pad 213 of the interposer 210 to a conductive redistribution pattern 312 of the interposer redistribution structure 310. That is, the through-electrode 212 may electrically connect the package substrate 110 to the interposer redistribution structure 310.

The through-electrode 212 may include a conductive plug and a barrier film surrounding the conductive plug. The conductive plug may include, for example, tungsten (W), titanium (Ti), aluminum (Al), or copper (Cu). The conductive plug may be formed through a plating process, a physical vapor deposition (PVD) process, or a chemical vapor deposition (CVD) process. The barrier film may include an insulating barrier film and/or a conductive barrier film. The insulating barrier film may include an oxide film, a nitride film, a carbide film, polymer, or a combination thereof. The conductive barrier film may be located between the insulating barrier film and the conductive plug. The conductive barrier film may include, for example, metal compounds, such as tungsten nitride (WN), titanium nitride (TiN), and tantalum nitride (TaN). The barrier film may be formed through a plating process, a PVD process, or a CVD process.

The interposer pad 213 may be disposed on the first surface of the interposer 210. The interposer pad 213 may be connected to a lower end portion of the through-electrode 212, and the number of interposer pads 213 may correspond to the number of through-electrodes 212. The interposer pad 213 may include a metal material, and the metal material may include tungsten (W), titanium (Ti), aluminum (Al), or copper (Cu).

The interposer connection terminal 214 may be located between the interposer pad 213 and an upper pad 112 of the package substrate 110. The interposer connection terminal 214 may be configured to electrically connect the interposer 210 to the package substrate 110. The number of interposer connection terminals 214 may correspond to the number of interposer pads 213. The interposer connection terminal 214 shown in FIG. 6 is an example of the solder ball 20 (see FIG. 1) described with reference to FIGS. 1 to 3.

The interposer redistribution structure 310 may be disposed on the second surface of the interposer 210 and include a redistribution insulating layer 311, a conductive redistribution pattern 312, and a connection pad 313. The redistribution insulating layer 311 may be disposed on the second surface of the interposer substrate 211 and include silicon oxide or silicon nitride. The conductive redistribution pattern 312 may electrically connect the first and second memory devices 400a and 400b to each other. As shown in FIG. 6, the conductive redistribution pattern 312 may electrically connect the first and second memory devices 400a and 400b to the interposer 210. The conductive redistribution pattern 312 may include one or more layers of metal wires and contact vias. The contact via may electrically connect metal wires to each other or electrically connect the metal wire to the connection pad 313. The conductive redistribution pattern 312 may electrically and physically connect the through-electrode 212 to the connection pad 313. The conductive redistribution pattern 312 and the connection pad 313 may include a metal material, for example, at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn).

The first memory device 400a and the second memory device 400b may include the plurality of memory chips 410a and 410b, respectively, each of which has a vertically stacked structure. For example, the plurality of memory chips 410a may include a first integrated circuit device 411a, a second integrated circuit device 412a, a third integrated circuit device 413a, and a fourth integrated circuit device 414a, which are stacked in the vertical direction. Further, the plurality of memory chips 410b may include a first integrated circuit device 411b, a second integrated circuit device 412b, a third integrated circuit device 413b, and a fourth integrated circuit device 414b, which are stacked in the vertical direction.

In some example embodiments, the first memory device 400a and the second memory device 400b may each include a stacked memory device. For example, the first memory device 400a and the second memory device 400b may have a 3-dimensional memory structure in which a plurality of chips are stacked. For example, the first memory device 400a and the second memory device 400b may be provided based on high bandwidth memory (HBM) or hybrid memory cube (HMC) standards. In this case, the first integrated circuit devices 411a and 411b located as the lowermost layer may function as buffer dies, and the second to fourth integrated circuit devices 412a, 412b, 413a, 413b, 414a and 414b may function as core dies. For example, the buffer die may also be referred to as an interface die, a base die, a logic die, a master die, etc., and the core die may also be referred to as a memory die, a slave die, etc. FIG. 6 illustrates that the first memory device 400a and the second memory device 400b include three core dies, but the number of core dies may vary. For example, the first memory device 400a may include 4, 8, 12, or 16 core dies.

A first group of connection pads 313, a first group of the connection terminals 314, and second underfills 420a surrounding the connection pads 313 and the connection terminals 314 may be arranged between the first memory device 400a and the interposer 210, and a second group of Connection pads 313, a second group of the connection terminals 314, and second underfills 420b surrounding the connection pads 313 and the connection terminals 314 may be arranged between the second memory device 400b and the interposer 210. For example, the second underfills 420a and 420b may include at least one of an insulating polymer or an epoxy resin. For example, the material constituting the second underfills 420a and 420b may include an EMC. The connection terminal 314 shown in FIG. 6 is an example of the solder ball 20 (see FIG. 1) described with reference to FIGS. 1 to 3.

Further, adhesive layers 450a and 450b may be respectively arranged between the first integrated circuit device 411a and the second underfill 420a of the first memory device 400a and between the first integrated circuit device 411b and the second underfill 420b of the second memory device 400b. The adhesive layers 450a and 450b may be configured to bond the second underfills 420a and 420b to the first integrated circuit devices 411a and 411b, respectively.

According to an example embodiment, the semiconductor package 100c may include molding layers 430a and 430b that surround the second to fourth integrated circuit devices 412a, 413a, and 414a of the first memory device 400a and the second to fourth integrated circuit devices 412b, 413b, and 414b of the second memory device 400b, respectively. For example, the molding layers 430a and 430b may each include an EMC.

According to an example embodiment, the semiconductor package 100c may further include a package molding layer 460 configured to seal the first memory device 400a and the second memory device 400b. Also, the package molding layer 460 may surround the sidewalls of the molding layers 430a and 430b, the sidewall of the first integrated circuit device 411a of the first memory device 400a, and the sidewall of the first integrated circuit device 411b of the second memory device 400b. The package molding layer 460 may be disposed on the interposer redistribution structure 310, and the outward-facing sidewall of the package molding layer 460 may be located on the same plane as the sidewall of the interposer redistribution structure 310. For example, the package molding layer 460 may include an EMC.

The semiconductor package 100c may further include a heat dissipation member 470 that covers the upper surfaces of the first memory device 400a and the second memory device 400b. The heat dissipation member 470 may include a heat dissipation plate, such as a heat slug and a heat sink. In some example embodiments, the heat dissipation member 470 may surround the first memory device 400a, the second memory device 400b, and the interposer 210 above the upper surface of the package substrate 110.

Also, the semiconductor package 100c may further include a thermal interface material (TIM) 450. The heat dissipation member 470 may be located between the TIM 450 and the first memory device 400a and between TIM 450 and the second memory device 400b.

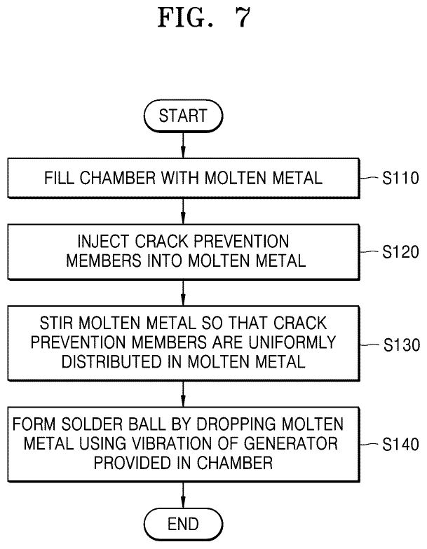

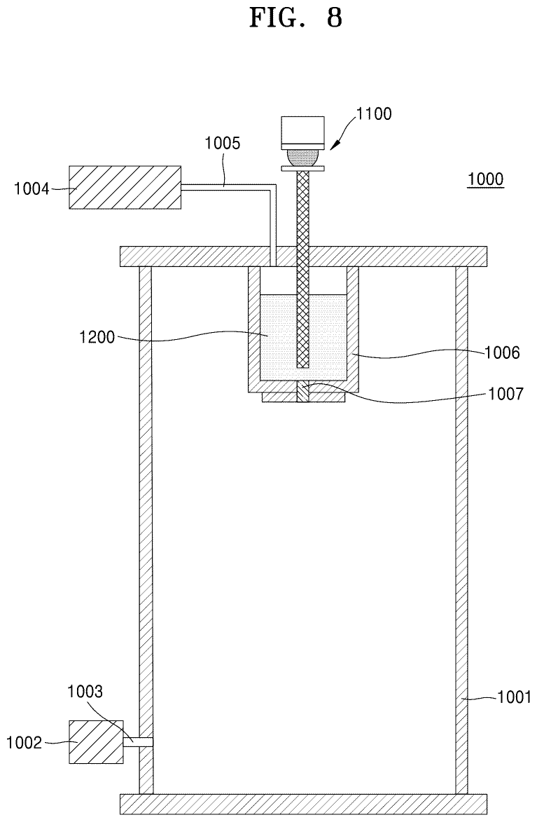

FIG. 7 is a flowchart of a method of manufacturing a solder ball, according to an example embodiment, and FIGS. 8 to 11 are diagrams sequentially showing a process of manufacturing the solder ball, according to an example embodiment. Descriptions are given below with reference to FIGS. 8 to 11 together with FIG. 7.

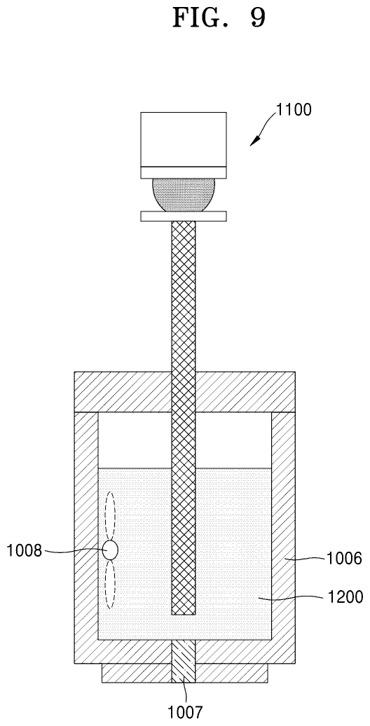

Referring to FIGS. 8 and 9 together with FIG. 7, the method of manufacturing the solder ball (hereinafter, referred to as the solder ball manufacturing method) according to an example embodiment includes filling a second chamber 1006 with molten metal 1200 (S110). Solder ball manufacturing equipment 1000 may include a first chamber 1001, a first gas supply source 1002, a first supply pipe 1003, a second gas supply source 1004, a second supply pipe 1005, the second chamber 1006, a nozzle 1007, and a generator 1100.

The first chamber 1001 provides the inner space that may accommodate solder balls dropped from the second chamber 1006. The first supply pipe 1003 may be connected to the outer wall of the first chamber 1001, and the first gas supply source 1002 may be located outside the first chamber 1001. The first supply pipe 1003 may provide a passage through which the gas stored in the first gas supply source 1002 may flow in and out of the first chamber 1001. The gas flowing in and out of the first gas supply source 1002 may include an inert gas, such as argon (Ar) and helium (He).

The second gas supply source 1004 may be located outside the second chamber 1006 and the first chamber 1001. The second supply pipe 1005 may provide a passage through which the gas stored in the second gas supply source 1004 may flow in and out of the second chamber 1006. The gas flowing in and out of the second gas supply source 1004 may include an inert gas, such as argon (Ar) and helium (He).

The second chamber 1006 may be located in an upper end portion inside the first chamber 1001. The second chamber 1006 may provide a space for accommodating the molten metal 1200. The inside of the first chamber 1001 and the inside of the second chamber 1006 may be maintained at a constant vacuum state by a vacuum pump. Also, the vacuum level of the first chamber 1001 is maintained at a higher vacuum level than the vacuum level of the second chamber 1006 so that the molten metal 1200 in the second chamber 1006 falls into the first chamber 1001. For example, the vacuum level of the second chamber 1006 may be in a range from about 8 Torr to about 12 Torr and the vacuum level of the first chamber 1001 may be in a range from about 4×10⁻² Torr to about 6×10⁻² Torr. For example, the vacuum level of the second chamber 1006 may be 10 Torr and the vacuum level of the first chamber 1001 may be 5×10⁻² Torr.

The inside of the second chamber 1006 may be maintained at a constant temperature so that the molten metal 1200, which includes a material for the solder member 21 (see FIG. 1), is maintained in a liquid state.

The nozzle 1007 having one or more openings may be formed in a lower end portion of the second chamber 1006. The molten metal 1200 accommodated in the second chamber 1006 may fall into the first chamber 1001 via the nozzle 1007.

The inner space of the second chamber 1006 according to an example embodiment may be filled with the molten metal 1200. The molten metal 1200 may be a material for the solder member 21 (see FIG. 1) and may include tin (Sn). Also, according to some example embodiments, the molten metal 1200 may also include dopants that include indium (In), bismuth (Bi), antimony (Sb), copper (Cu), silver (Ag), zinc (Zn), lead (Pb), and/or an alloy thereof.

In addition, the solder ball manufacturing equipment 1000 may further include a rotary member 1008 that is submerged in the molten metal 1200 inside the second chamber 1006. This is described below in detail.

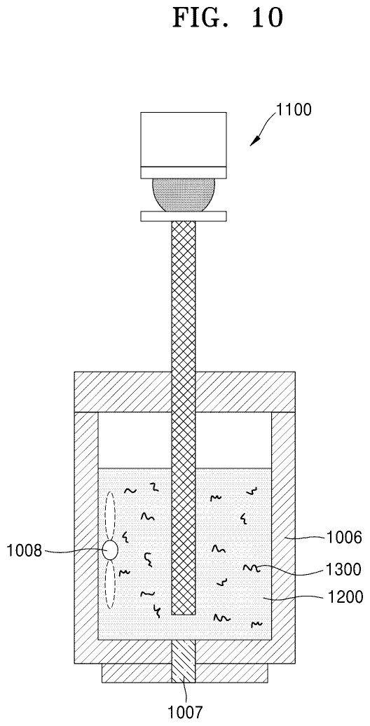

Referring to FIG. 10 together with FIG. 7, the solder ball manufacturing method according to an example embodiment may include injecting a crack prevention member 1300 into the molten metal 1200 (S120).

According to an example embodiment, crack prevention members 1300 may be injected into the molten metal 1200 accommodated in the second chamber 1006. The crack prevention member 1300 is the same as the crack prevention member 22 shown in FIGS. 1 to 3. The inner space of the second chamber 1006 may be maintained at a high temperature so as to maintain the molten metal 1200 in a liquid state. However, because the melting point of the crack prevention member 1300 is higher than that of the molten metal 1200, the crack prevention member 1300 is not melted and may be maintained in a solid state. The temperature inside the second chamber 1006 may be set to be higher than the melting point of the molten metal 1200 and to be lower than the melting point of the crack prevention member 1300.

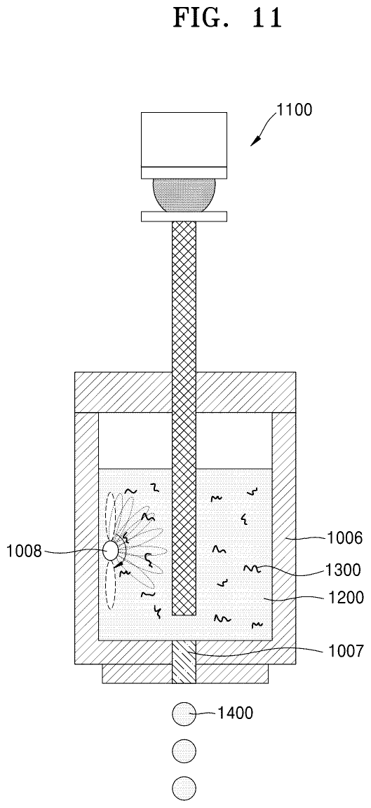

Referring to FIG. 11 together with FIG. 7, the solder ball manufacturing method according to an example embodiment may include stirring the molten metal 1200 so that the crack prevention members 1300 are uniformly distributed in the molten metal 1200 (S130).

The rotary member 1008 submerged in the molten metal 1200 may be located inside the second chamber 1006. For example, the rotary member 1008 may include a propeller that rotates by the electric force of a power source, such as a motor. However, example embodiments are not necessarily limited thereto, and the rotary member 1008 may include a stirrer that rotates by the magnetic force. That is, the rotary member 1008 includes a device configured to stir the molten metal 1200 using the rotational force.

FIG. 11 illustrates that the rotary member 1008 is disposed only on one sidewall inside the second chamber 1006. However, in order for the crack prevention members 1300 to spread uniformly in the molten metal 1200, it is desirable that a plurality of rotary members 1008 are evenly spaced apart from each other inside the second chamber 1006.

The crack prevention members 1300 may be uniformly distributed in the molten metal 1200 by stirring the molten metal 1200 using the rotary member 1008. Accordingly, when forming a solder ball 1400 (see FIG. 11), the specific gravity of the crack prevention members 1300 buried in each of solder balls 1400 (see FIG. 11) may be maintained within an error range.

Referring to FIG. 11 together with FIG. 7, the solder ball manufacturing method according to an example embodiment may include generating vibration with the generator 1100 provided in the second chamber 1006 so as to drop the molten metal 1200, thereby forming the solder balls 1400 (S140).

The generator 1100 may be partially submerged in the molten metal 1200. The generator 1100 may be installed in a central region of the second chamber 1006 and form the solder ball 1400 by dropping the molten metal 1200 with high amplitude vibration. The generator 1100 may vibrate at a frequency of about 300 Hz to about 5000 Hz to form the solder ball 1400 in which the molten metal 1200 has a diameter in a range from about 20 micrometers to about 800 micrometers. The solder ball 1400 falling from the second chamber 1006 expands due to the vacuum level inside the first chamber 1001 and has a perfect spherical shape. The solder ball 1400 shown in FIG. 11 has the same configuration as the solder ball 20 described with reference to FIGS. 1 to 3.

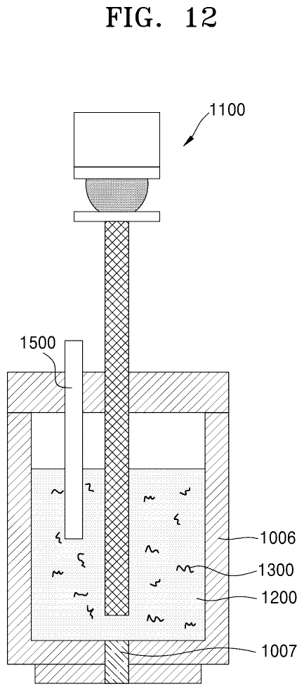

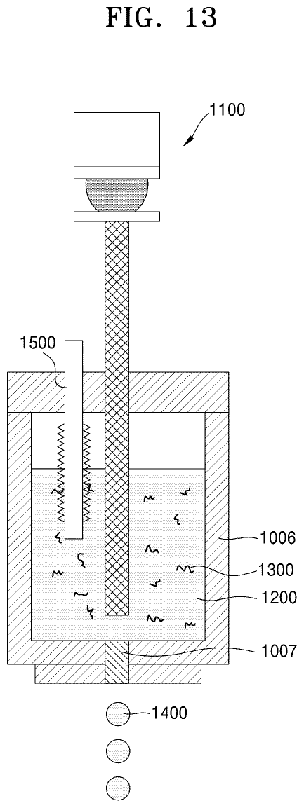

FIGS. 12 and 13 are diagrams sequentially showing a process of manufacturing a solder ball 1400, according to an example embodiment.

The method of manufacturing the solder ball 1400 shown in FIGS. 12 and 13 may include stirring the molten metal 1200 using a vibration member 1500 instead of the rotary member 1008, when compared to the method of manufacturing the solder ball 1400 shown in FIGS. 8 to 11. According to an example embodiment, the vibration member 1500 may be partially submerged in the molten metal 1200. The vibration member 1500 may be installed to be spaced apart from the bottom surface of the second chamber 1006 and may stir the molten metal 1200 at high amplitude vibration.

For example, the vibration member 1500 may vibrate at a frequency of about 100 Hz to about 10,000 Hz and may stir the molten metal 1200 so that the crack prevention members 22 (see FIG. 1) floating in the molten metal 1200 are uniformly distributed in the molten metal 1200. The crack prevention members 22 (see FIG. 1) are uniformly distributed in the molten metal 1200 by stirring the molten metal 1200 using the vibration member 1500. Accordingly, when forming a solder ball 1400, the specific gravity of the crack prevention members 22 (see FIG. 1) buried in each of solder balls 1400 may be maintained within an error range.

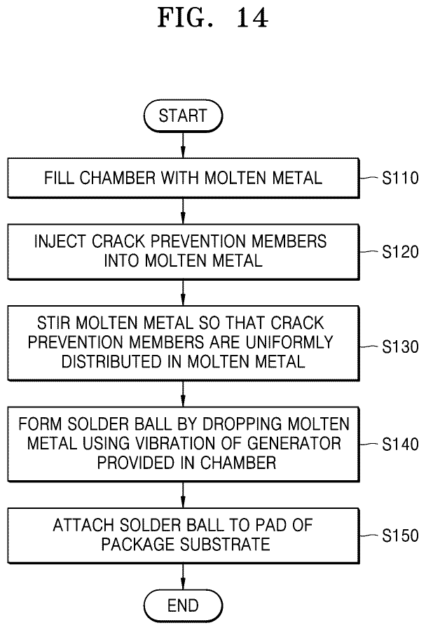

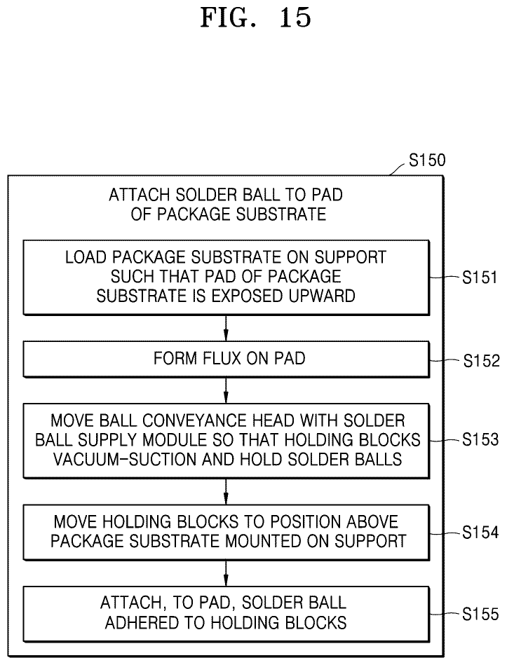

FIGS. 14 and 15 are flowcharts of a method of manufacturing a semiconductor package, according to an example embodiment.

Referring to FIG. 14, the method of manufacturing a semiconductor package according to an example embodiment may further include attaching a solder ball to a pad of a package substrate, when compared to the solder ball manufacturing method shown in FIG. 7. Therefore, descriptions of the operations already given above with reference to FIG. 7 are omitted.

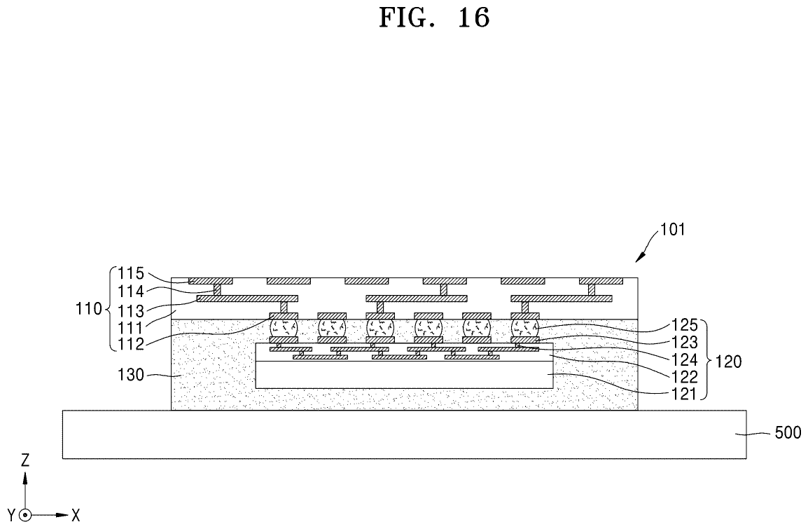

FIGS. 16 to 23 are diagrams sequentially showing a process of manufacturing a semiconductor package including solder balls, according to an example embodiment.

Hereinafter, an operation of attaching a solder ball to a lower pad 115 is described in detail with reference to FIGS. 16 to 23 together with FIGS. 14 and 15.

A semiconductor package 101 shown in FIG. 16 represents a semiconductor package in a state before the solder ball 116 is attached to the semiconductor package 100a of FIG. 4. Therefore, detailed descriptions of the components already given above with reference to FIG. 4 are omitted.

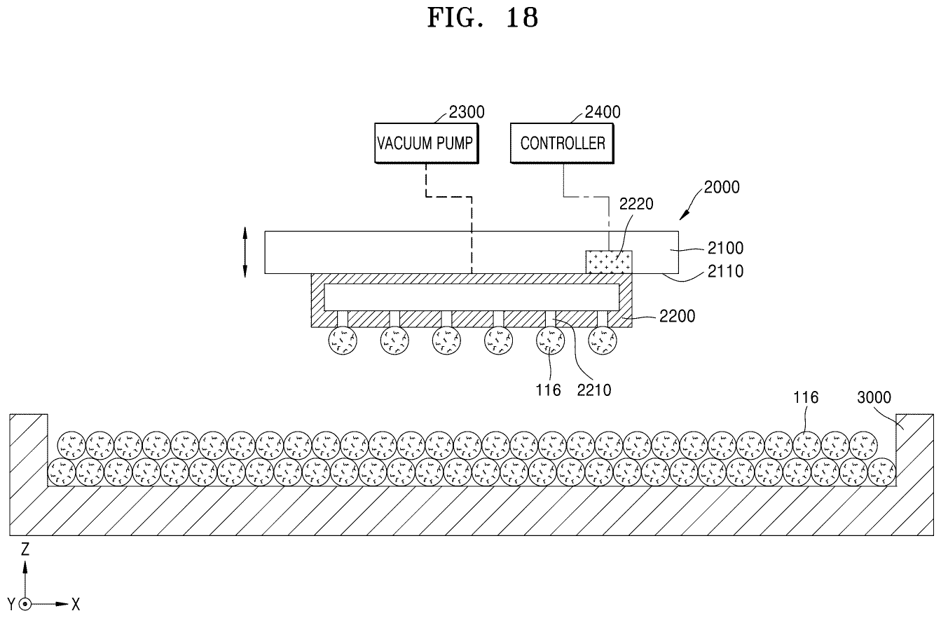

The solder ball 116 (see FIG. 4) described with reference to FIG. 4 is the same component as the solder ball 116 (see FIG. 18).

Referring to FIG. 16 together with FIGS. 14 and 15, attaching of the solder ball 116 (see FIG. 18) to the lower pad 115 (S150) may include loading a package substrate 110 on a support 500 such that the lower pad 115 of the package substrate 110 is exposed upward. The lower surface of the lower pad 115 of the package substrate 110 may be exposed to the outside in a vertical direction (a Z direction), and the upper surface of the molding layer 130 may face the support 500. The semiconductor package 101 may be provided on the support 500 in a state in which a chip bonding process of bonding a semiconductor chip 120 to the package substrate 110 and a molding process of molding the semiconductor chip 120 have been completed.

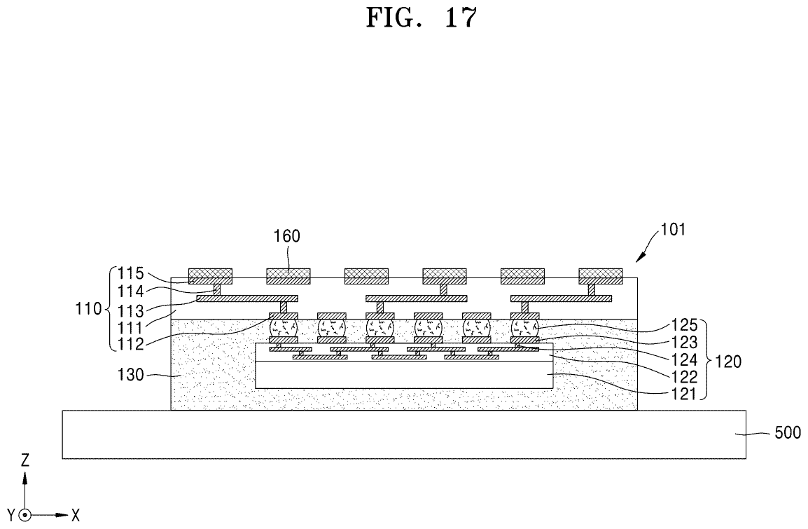

Referring to FIG. 17 together with FIG. 15, the attaching the solder ball 116 (see FIG. 18) to the lower pad 115 of the package substrate 110 (S150) may include forming a flux 160 on the lower pad 115 (S152). For example, a flux tool may apply a flux material onto each of lower pads 115 in a dotting manner. The flux may include an inorganic flux, an organic flux, a rosin-based flux, a water-soluble flux, or a combination thereof.

Referring to FIG. 18 together with FIG. 15, the attaching the solder ball 116 to the lower pad 115 of the package substrate 110 (S150) may include moving a ball conveyance head 2000 with a solder ball supply module so that holding blocks 2200 vacuum-suction and hold the solder balls 116 (S153).

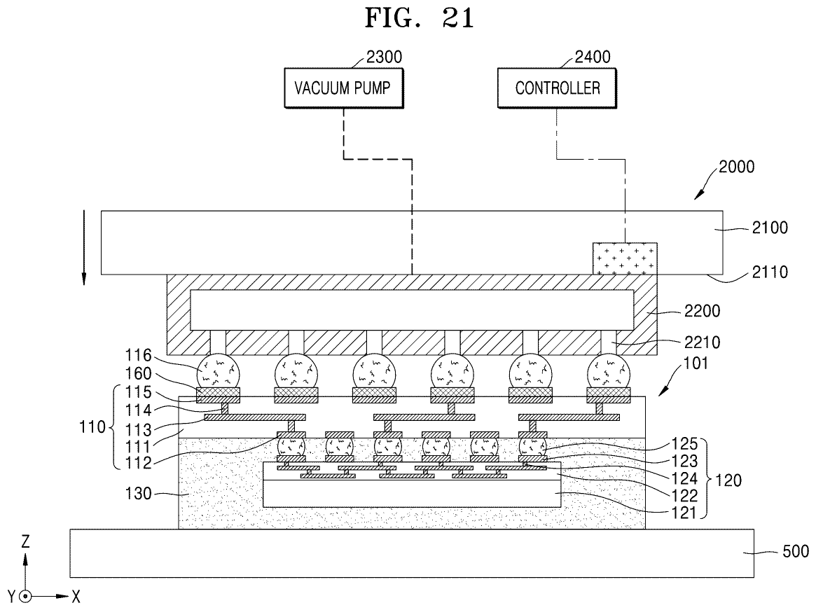

The ball conveyance head 2000 according to an example embodiment may be configured to perform a ball attachment process for attaching the plurality of solder balls 116 to the lower pads 115, respectively (see FIG. 16). For example, a series of operations may be performed. the ball conveyance head 2000 suctions and supports the plurality of solder balls 116 supplied from the solder ball supply module, the ball conveyance head 2000 to which the plurality of solder balls 116 have been attached is conveyed above a support 500 (see FIG. 17) on which the package substrate 110 (see FIG. 16) is mounted, and the plurality of solder balls 116 are attached to the package substrate 110 (see FIG. 21).

The ball conveyance head 2000 may include a base 2100 and a plurality of holding blocks 2200 mounted on the base 2100. The base 2100 may include a first surface 2110 on which a holding block 2200 is mounted. The base 2100 may be configured to move in the lateral directions (the X direction and/or the Y direction). Further, the base 2100 may be configured to move in the vertical direction (the Z direction). For example, the base 2100 may move in the vertical direction (the Z direction) and adjust the distance between the plurality of holding blocks 2200 and the support 500 (see FIG. 17) or the distance between the holding blocks 2200 and a ball box 3000. This movement of the base 2100 may be performed by an actuator 2220 provided in the ball conveyance head 2000.

The holding block 2200 may include a bottom surface to which the plurality of solder balls 116 are attached. The holding block 2200 may include vacuum passages 2210 extending from the bottom surface of the holding block 2200. For example, each of the vacuum passages 2210 may communicate with one cavity provided in the holding block 2200.

A vacuum pump 2300 may be located outside the ball conveyance head 2000 so as to apply vacuum pressure to the vacuum passages 2210. The vacuum pump 2300 may adjust the pressure in the vacuum passage 2210 so that the solder ball 116 is attached to the bottom surface of the holding block 2200 or the solder ball 116 is separated from the holding block 2200.

For example, when the bottom surface of the holding block 2200 is located adjacent to the solder ball 116 and the vacuum pump 2300 applies vacuum pressure to each of the vacuum passages 2210 of the holding block 2200, the solder balls 116 may be vacuum-suctioned to ends of the vacuum passages 2210 exposed via the bottom surface of the holding block 2200. That is, when the vacuum pump 2300 applies the vacuum pressure to the vacuum passages 2210 of the holding block 2200, the solder ball 116 may be attached to the bottom surface of the holding block 2200 as lower pressure than the surrounding pressure is formed near the bottom surface of the holding block 2200. In addition, the vacuum pump 2300 may release or terminate the vacuum pressure in the vacuum passage 2210 of the holding block 2200, and thus, the solder ball 116 may be separated from the holding block 2200.

The solder ball supply module may include, for example, a ball box 3000 containing the solder balls 116 and a vibrator capable of vibrating the ball box 3000. When the holding block 2200 of the ball conveyance head 2000 is located close to the solder balls 116 accommodated in the ball box 3000, the vibrator applies vibration to the ball box 3000 so that the solder balls 116 bounce toward the bottom surface of the holding block 2200. At this moment, the solder balls 116 may be vacuum-suctioned to the bottom surface of the holding block 2200 by the vacuum pressure applied to the vacuum passages 2210 of the holding block 2200.

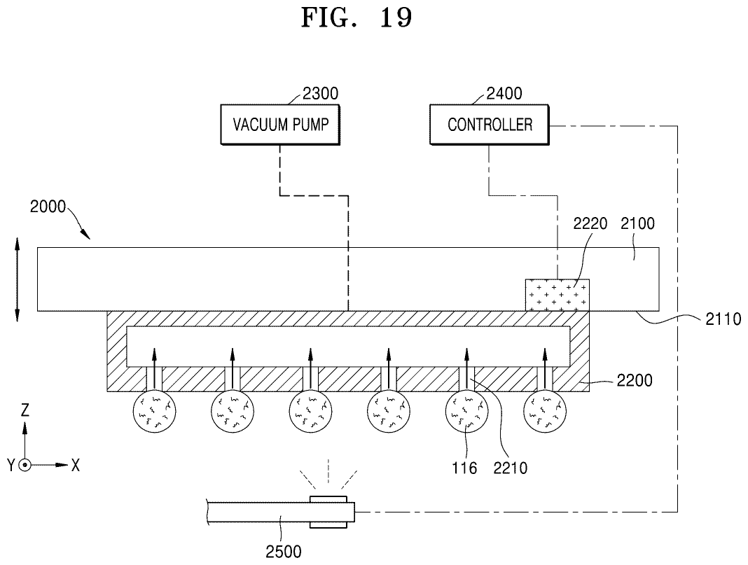

Referring to FIG. 19, the attaching of the solder ball 116 to the lower pad 115 of the package substrate 110 (S150) may include obtaining an image signal by capturing images of the holding blocks 2200 of the ball conveyance head 2000 before moving the holding blocks 2200 to a position above the package substrate 110.

An image capturing unit 2500 may be located below the ball conveyance head 2000. The image capturing unit 2500 may include a camera with an image sensor. The image capturing unit 2500 may be configured to capture the image of the package substrate 110 mounted on the support 500 and/or the image of the holding block 2200 provided in the ball conveyance head 2000. The image capturing unit 2500 may transmit, to a controller 2400, image signals obtained by capturing the image of the package substrate 110 mounted on the support 500 and/or the image of the holding block 2200 in the ball conveyance head 2000.

The controller 2400 may include an image processor capable of processing the image signals obtained from the image capturing unit 2500. The controller 2400 may detect the positions of the holding block 2200 on the basis of the image signals obtained from the image capturing unit 2500. For example, the controller 2400 may detect the relative position of each of the plurality of holding blocks 2200 above the package substrate 110 in the first horizontal direction (the X direction) and the second horizontal direction (the Y direction) with respect to a certain or preset reference position. Also, the controller 2400 may detect the relative position of each of the holding blocks 2200 in the first horizontal direction (the X direction) and the second horizontal direction (the Y direction) with respect to a certain or preset reference position.

The controller 2400 may adjust the distances between the holding blocks 2200 on the basis of the detected positions of the lower pads 115 of the package substrate 110. The controller 2400 may apply drive control signals to actuators 2220 connected to the holding blocks 2200 and adjust the position of each of the holding blocks 2200. For example, each of the holding blocks 2200 may be moved and aligned with the lower pad 115 of the corresponding package substrate 110.

The controller 2400 may be provided as hardware, firmware, software, or any combination thereof. For example, the controller 2400 may include computing devices, such as a workstation computer, a desktop computer, a laptop computer, and a tablet computer. For example, the controller 2400 may include memory devices, such as read only memory (ROM) and random access memory (RAM), processors configured to perform certain operations and algorithms, for example, a microprocessor, a central processing unit (CPU), a graphics processing unit (GPU), etc. In addition, the controller 2400 may include a receiver and a transmitter for receiving and transmitting electrical signals.

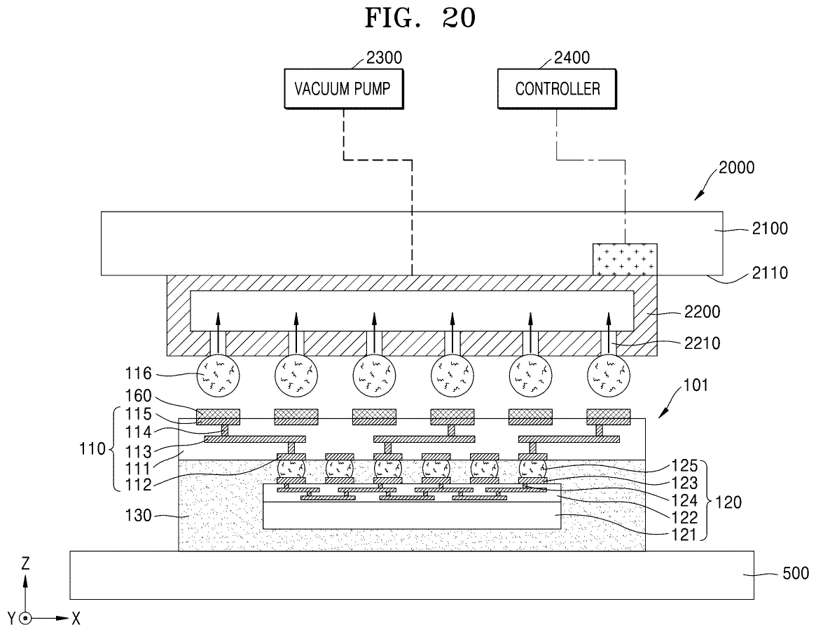

Referring to FIG. 20, the attaching of the solder ball 116 to the lower pad 115 of the package substrate 110 (S150) may include moving the holding blocks 2200 to a position above the package substrate 110 mounted on the support 500.

According to an example embodiment, the ball conveyance head 2000 may be aligned with the package substrate 110 mounted on the support 500. Also, the holding block 2200 may be aligned close to the package substrate 110. The solder balls 116 suctioned to the ends of the vacuum passages 2210 in the holding block 2200 may be arranged above the lower pads 115 of the package substrate 110.

Referring to FIG. 21 together with FIG. 15, the attaching of the solder ball 116 to the lower pad 115 of the package substrate 110 may include attaching, onto pads, the solder balls 116 suctioned to the holding blocks 2200 (S155).

According to an example embodiment, the ball conveyance head 2000 may descend to a position at which the solder ball 116 suctioned to the holding block 2200 comes into contact with the lower pad 115, and the vacuum pump 2300 may release the vacuum pressure applied to the vacuum passage 2210 of the holding block 2200 so that the solder ball 116 may be separated from the holding block 2200. Subsequently, when the ball conveyance head 2000 moves in a direction away from the support 500, each of the solder balls 116 may be fixed to the lower pad 115 by the adhesive force of the flux 160.

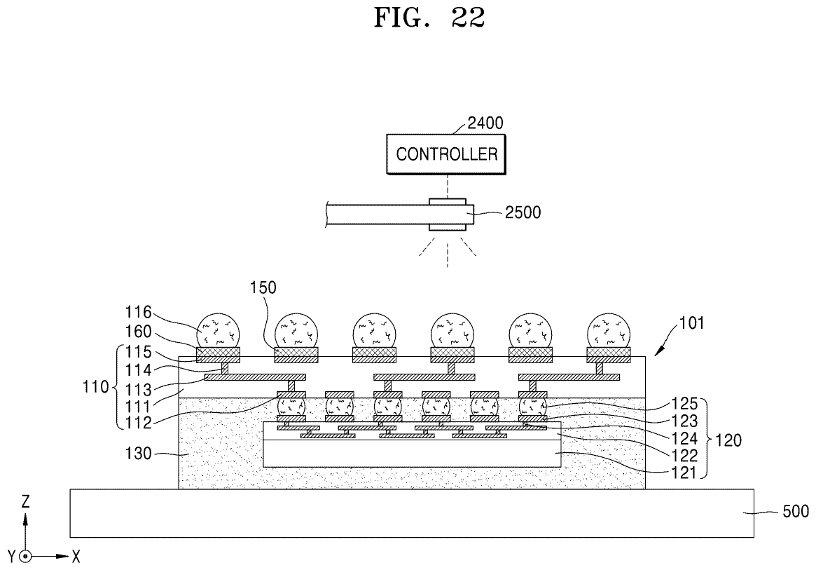

Referring to FIG. 22, the attaching of the solder ball 116 to the lower pad 115 of the package substrate 110 (S150) may include obtaining an image signal by capturing an image of the package substrate 110 to which the solder ball 116 is attached.

The image capturing unit 2500 may be located above the package substrate 110. The image capturing unit 2500 may transmit, to the controller 2400, the image signals that are obtained by capturing the image of the package substrate 110 which is mounted to the support 500 and to which the solder balls 116 are attached.

The controller 2400 may detect the positions of the solder balls 116 on the basis of the image signals obtained from the image capturing unit 2500. For example, the controller 2400 may detect the relative position of each of the solder balls 116 above the package substrate 110 in the first horizontal direction (the X direction) and the second horizontal direction (the Y direction) with respect to a certain or preset reference position. Further, the controller 2400 may detect the relative position of each of the solder balls 116 in the first horizontal direction (the X direction) and the second horizontal direction (the Y direction) with respect to a certain or preset reference position. If the position of the solder ball 116 is outside the error range from the certain or preset reference position, the semiconductor package is determined to be defective.

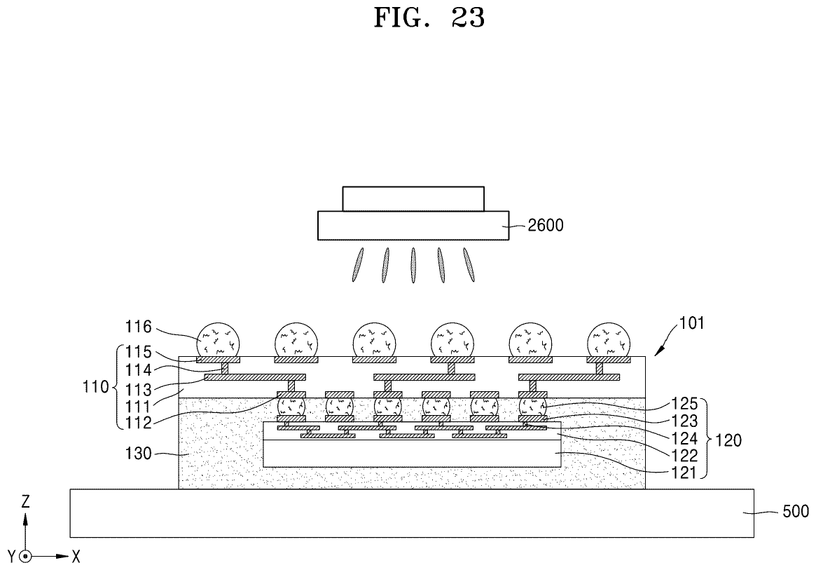

Referring to FIG. 23, the attaching of the solder ball 116 to the lower pad 115 of the package substrate 110 may include performing a reflow process and cleaning.

When the solder balls 116 are attached to the lower pads 115 of the package substrate 110, the reflow process and the cleaning process of the flux 160 (see FIG. 22) may be performed on the package substrate 110. The package substrate 110 is put into a reflow oven having a heat source during the reflow process, and the solder balls 116 may be bonded to the lower pads 115, respectively, under high temperature conditions applied by the heat source. After the reflow process, the cleaning process of the flux 160 (see FIG. 22) may be performed to remove the remaining flux 160 (see FIG. 22) using a cleaning device 2600.

While the inventive concepts have been particularly shown and described with reference to some example embodiments thereof, it will be understood that various changes in form and details may be made therein without departing from the spirit and scope of the following claims.

1. A solder ball comprising:
a solder member having a spherical shape; and
crack prevention members comprising a plurality of conductive wires irregularly distributed in the solder member and ceramic coating layers covering surfaces of the plurality of conductive wires.

2. The solder ball of claim 1, wherein a diameter of the solder member is in a range from 20 micrometers to 800 micrometers.

3. The solder ball of claim 1, wherein
a cross-sectional diameter of each of the plurality of conductive wires is in a range from 1 micrometer to 50 micrometers, and
a length of each of the plurality of conductive wires is in a range from 1 micrometer to 100 micrometers.

4. The solder ball of claim 1, wherein a melting point of the crack prevention members is higher than a melting point of the solder member.

5. The solder ball of claim 1, wherein an amount of the crack prevention members is in a range from 2 wt % to 60 wt %.

6. The solder ball of claim 1, wherein the conductive wires in the solder member are not in contact with an outer circumferential portion of the solder member.

7. The solder ball of claim 1, wherein the solder member comprises Sn, and
the conductive wires comprise Fe, Ti, Au, Ag, Cu, Al, or a combination thereof.

8. A semiconductor package comprising:
a first package substrate;
at least one semiconductor chip mounted on the first package substrate using a flip chip method; and
a first solder ball attached to an active surface of the at least one semiconductor chip,
wherein the first solder ball comprises
a first solder member having a spherical shape, and
first crack prevention members comprising a plurality of first conductive wires irregularly distributed in the first solder member and first ceramic coating layers covering surfaces of the plurality of first conductive wires.

9. The semiconductor package of claim 8, further comprising:
a conductive pad on the first package substrate,
wherein the first solder ball is attached to the conductive pad.

10. The semiconductor package of claim 8, further comprising:
a second solder ball attached to a lower surface of the first package substrate, wherein the second solder ball comprises
a second solder member having a spherical shape, and
second crack prevention members comprising a plurality of second conductive wires irregularly distributed in the second solder member and second ceramic coating layers covering surfaces of the plurality of second conductive wires.

11. The semiconductor package of claim 10, wherein a diameter of the second solder ball is greater than a diameter of the first solder ball.

12. The semiconductor package of claim 8, further comprising:
an interposer substrate located between the first package substrate and the at least one semiconductor chip; and
a third solder ball attached to a lower surface of the interposer substrate,
wherein the third solder ball comprises
a third solder member having a spherical shape, and
third crack prevention members comprising a plurality of third conductive wires irregularly distributed in the third solder member and third ceramic coating layers covering surfaces of the plurality of third conductive wires.

13. The semiconductor package of claim 8, further comprising:
a second package substrate on the at least one semiconductor chip; and
a connector attached to an upper surface of the first package substrate and a lower surface of the second package substrate and electrically connecting the first package substrate to the second package substrate,
wherein the connector comprises,
a fourth solder member having a spherical shape, and
fourth crack prevention members comprising a plurality of fourth conductive wires irregularly distributed in the fourth solder member and fourth ceramic coating layers covering surfaces of the plurality of fourth conductive wires.

14. The semiconductor package of claim 13, wherein a vertical length of the connector is greater than a vertical length of the first solder ball.

15. A method of manufacturing a solder ball, the method comprising:
filling a chamber with molten metal;
injecting crack prevention members into the molten metal;
stirring the molten metal so that the crack prevention members are uniformly distributed in the molten metal; and
forming the solder ball by dropping the molten metal using vibration of a generator in the chamber.

16. The method of claim 15, wherein each of the crack prevention members comprises a conductive wire and a ceramic coating layer covering a surface of the conductive wire.

17. The method of claim 16, wherein
a cross-sectional diameter of the conductive wire is in a range from 1 micrometer to 50 micrometers, and
a length of the conductive wire is in a range from 1 micrometer to 100 micrometers.

18. The method of claim 15, wherein the forming of the solder ball comprises vibrating the generator at a frequency of 300 Hz to 5000 Hz.

19. The method of claim 15, wherein the stirring of the molten metal comprises stirring the molten metal by rotating a rotary member that is provided in the chamber and submerged in the molten metal.

20. The method of claim 15, wherein the stirring of the molten metal comprises stirring the molten metal by vibrating a vibration member that is provided in the chamber and submerged in the molten metal.

21-25. (canceled)
